(19) United States
(12) Patent Application Publication
(10) Pub. No.: US 2026/0156901 A1
(43) Pub. Date: Jun. 4, 2026

(54) III-N DEVICES WITH PARASITIC CURRENT SUPPRESSION

(71) Applicant: TEXAS INSTRUMENTS INCORPORATED, Dallas, TX (US)

(72) Inventor: Dong Seup Lee, Allen, TX (US)

(21) Appl. No.: 18/963,843

(22) Filed: Nov. 29, 2024

(51) Int. Cl. H01L 29/423; H01L 29/66; H01L 29/778

(52) U.S. Cl. CPC H10D 64/519; H10D 30/015; H10D 30/475

(57) ABSTRACT

Group III-N semiconductor devices including parasitic current suppression are described. In one example, a semiconductor device comprises a semiconductor substrate including an active area and an isolation region surrounding the active area. The active area includes a source region, a gate region, and a drain region, where the source region, the gate region, and the drain region extend parallel to one another. A III-N heterojunction structure is disposed over the semiconductor substrate, the III-N heterojunction structure including a buffer layer over the semiconductor substrate and a barrier layer over the buffer layer. A III-N gate layer is disposed over the barrier layer, the III-N gate layer including a gate portion disposed in the gate region and a gate extension extended from the gate portion to the isolation region.

### FIELD OF THE DISCLOSURE

Disclosed implementations relate generally to the field of group III-N semiconductor devices and their fabrication.

### BACKGROUND

Group III nitride materials (also referred to as III-N materials) possess a unique combination of physical and electrical properties found to be beneficial in modern microelectronics and optoelectronics. Among these properties are wide bandgap, high saturated drift velocity and breakdown voltage, high thermal conductivity, robust chemical and thermal stability, etc. Due to these characteristics, III-N materials are being considered as promising materials for fabrication of powerful high-frequency transistors capable of functioning at high temperatures and in hostile environments. Whereas advances in III-N devices and their fabrication continue to grow apace, several lacunae remain, thereby requiring further innovation as will be set forth hereinbelow.

### SUMMARY

The following presents a simplified summary in order to provide a basic understanding of some examples of the present disclosure. This summary is not an extensive overview of the examples, and is neither intended to identify key or critical elements of the examples, nor to delineate the scope thereof. Rather, the primary purpose of the summary is to present some concepts of the present disclosure in a simplified form as a prelude to a more detailed description that is presented in subsequent sections further below.

In one example, a semiconductor device comprises a semiconductor substrate including an active area and an isolation region surrounding the active area. The active area includes a source region, a gate region, and a drain region, where the source region, the gate region, and the drain region extend parallel to one another. A III-N heterojunction structure is disposed over the semiconductor substrate, the III-N heterojunction structure including a buffer layer over the semiconductor substrate and a barrier layer over the buffer layer. A III-N gate layer is disposed over the barrier layer, the III-N gate layer including a gate portion disposed in the gate region and a gate extension extended from the gate portion to the isolation region.

In one example, a method of fabricating a III-N semiconductor device is disclosed. The method comprises, among others, forming a III-N heterojunction structure over a semiconductor substrate including an active area and an isolation region surrounding the active area, where the active area includes a source region, a gate region, and a drain region, and the source, gate, and drain regions extending parallel to one another; and the III-N heterojunction structure includes a buffer layer over the semiconductor substrate and a barrier layer over the buffer layer; and forming a III-N gate layer over the barrier layer, the III-N gate layer including a gate portion disposed in the gate region; and a gate extension extended from the gate portion to the isolation region.

In one example, a semiconductor device comprises a semiconductor substrate including an active area and an isolation region surrounding the active area. A III-N heterojunction structure is disposed over the semiconductor substrate, the III-N heterojunction structure including a buffer layer over the semiconductor substrate and a barrier layer over the buffer layer. The semiconductor device includes a first III-N transistor formed in a first portion of the active area, the first III-N transistor including a first source region, a first drain region, and a first gate region, where the first source region, the first drain region, and the first gate region extend parallel to one another. The semiconductor device includes a second III-N transistor formed in a second portion of the active area, the second III-N transistor including a second source region, a second drain region, and a second gate region, where the second source region, the second drain region, and the second gate region extend parallel to one another. A III-N gate layer is disposed over the barrier layer, where the III-N gate layer includes a first gate portion disposed in the first gate region; a first gate extension extended from the first gate portion to the isolation region, the first gate extension being proximate to a terminal portion of the first source region; a second gate portion disposed in the second gate region; and a second gate extension extended from the second gate portion to the isolation region, the second gate extension being proximate to a terminal portion of the second source region.

### BRIEF DESCRIPTION OF THE DRAWINGS

Implementations of the present disclosure are illustrated by way of example, and not by way of limitation, in the Figures of the accompanying drawings. Different references to “an” or “one” implementation in this disclosure are not necessarily to the same implementation, and such references may mean at least one. Further, when a particular feature, structure, or characteristic is described in connection with an implementation, such feature, structure, or characteristic in connection with other implementations may be feasible whether or not explicitly described.

The accompanying drawings are incorporated into and form a part of the specification to illustrate one or more example implementations of the present disclosure. Various advantages and features of the disclosure are described in the following Detailed Description taken in connection with the appended claims and with reference to the attached drawing Figures in which:

FIGS. 1A-1F depict layouts of representative GaN devices where one or more III-N gate layer extensions may be provided for suppressing parasitic current paths according to some examples of the present disclosure;

FIG. 2A depicts a partial layout of a GaN device including one or more III-N gate layer extensions for mitigating current crowding according to an example;

FIG. 2B depicts a cross-sectional view of the GaN device shown in FIG. 2A along a sectional plane through a III-N gate layer;

FIG. 2C depicts a cross-section view of the GaN device shown in FIG. 2A along a sectional plane through III-N gate layer extensions extending to an isolation region; and

FIG. 3 is a flowchart of a method of fabricating a semiconductor device including one or more GaN devices according to some examples of the present disclosure.

### DETAILED DESCRIPTION

Examples of the disclosure are described with reference to the attached Figures where like reference numerals are generally utilized to refer to like elements. The Figures are not drawn to scale and they are provided merely to illustrate examples. Numerous specific details, relationships, and methods are set forth below to provide an understanding of one or more examples. However, some examples may be practiced without such specific details. In other instances, well-known subsystems, components, structures and techniques have not been shown in detail in order not to obscure the understanding of the examples. Accordingly, the examples of the present disclosure may be practiced without such specific components.

Additionally, terms such as “coupled” and “connected,” along with their derivatives, may be used in the following description, claims, or both. These terms are not necessarily intended as synonyms for each other. “Coupled” may be used to indicate that two or more elements, which may or may not be in direct physical or electrical contact with each other, co-operate or interact with each other. “Connected” may be used to indicate the establishment of communication, i.e., a communicative relationship, between two or more elements that are coupled with each other. Further, in one or more examples set forth herein, generally speaking, an element, component or module may be configured to perform a function if the element may be programmed for performing or otherwise structurally arranged to perform that function.

Without limitation, examples of the present disclosure will be set forth below in the context of improving performance characteristics of semiconductor devices based on Group III nitride materials, also referred to as III-N materials, such as gallium nitride (GaN) devices.

GaN devices, e.g., GaN transistors, provide certain performance advantages over silicon, including lower on-state resistance (e.g., drain-source resistance or R_{DSON}), lower switching losses, and improved breakdown voltage, among others. GaN transistors include a hetero epitaxy structure with a junction between materials of different bandgaps (e.g., a heterojunction structure), such as aluminum gallium nitride (AlGaN) and gallium nitride, to provide a 2-dimensional electron gas (2DEG) formed within the AlGaN/GaN hetero epitaxy structure that is used for device operation—e.g., forming a channel of the GaN device. The 2-dimensional electron gas (2DEG) may be referred to as a 2DEG channel. Depletion mode (DMODE) GaN transistors are normally on, whereas enhancement mode (EMODE) GaN transistors are normally off. In some examples, EMODE GaN transistors include a gate stack with a gallium nitride (p-GaN) layer including p-type dopants, such as magnesium (Mg) or other suitable p-type dopants. When the p-type dopants are activated, the p-GaN layer may deplete the 2DEG beneath the gate stack at zero or negative gate bias. Applying a positive gate voltage enhances the 2DEG under the gate and turns the EMODE GaN device on to allow current flow between the source and drain.

In some examples, a GaN device may be formed with one or more GaN layers over a suitable semiconductor substrate, e.g., including a silicon substrate. The one or more GaN layers may form a heterojunction structure over the semiconductor substrate, with a p-GaN layer overlying the heterojunction structure for effectuating EMODE device functionality. The p-GaN layer may include appropriate levels of p-type dopants to control the threshold voltage (V_{T} or V_{TH}) of the GaN device. In general, higher threshold voltages are desired in order to reduce the likelihood of accidentally turning on an EMODE device, increase operational margins, reduce leakage current (e.g., off-state I_{DS}), etc.

In some examples, a GaN process flow may include an implantation stage to achieve isolation of the devices where suitable implant species may be implanted in a defined area of the substrate. The implanted species cause damage to the crystallinity of the heterojunction structure in the defined area, thus disrupting or disabling the formation of a 2DEG channel in the defined area. Moreover, the isolation implant process may render a portion of the p-GaN layer (e.g., any portions of the p-GaN layer exposed to the isolation implant process) damaged such that the portion of p-GaN layer may become weakly-activated or deactivated. Consequently, the defined area is rendered inactive for forming GaN devices, resulting in an isolation region operating to isolate areas where GaN devices may be formed, which may be referred to as active areas, active regions, device areas or device regions. Because the active areas are not implanted with isolation implant species, the crystallinity of the heterojunction structure in the active areas is preserved.

In some arrangements, the isolation region may surround an active area where a GaN device is formed—e.g., an EMODE transistor including a p-GaN layer as part of the gate stack. The p-GaN layer may surround a drain region of the EMODE transistor to separate the drain region from a source region. Moreover, the entire p-GaN layer may be contained within the active area, thus creating extra channel area (e.g., in addition to the intended channel area directly between the source and drain regions that extend parallel to each other) near a terminal portion of the drain region. In such arrangements, undesirable current pathways (e.g., parasitic current paths) may be developed between the terminal portions of source and drain regions of the device, which may lead to current crowding at the drain region when the device is turned on. Under certain operating conditions, the current crowding may negatively affect device performance, e.g., reducing the device's safe operating area (SOA). In certain applications, e.g., power GaN applications, the issue of reduced SOA can be particularly disadvantageous.

To overcome current crowding and related performance issues, some arrangements may include having an isolation region disposed near the source and drain regions so as to deactivate (e.g., “cut-off”) any undesirable channel area outside the source/drain region (e.g., outside the intended channel area). As a result, portions of the p-GaN layer may extend past the active region and may be exposed to the isolation implant process. Consequently, the exposed portions of the p-GaN layer may be damaged (e.g., deactivated) and may lose its ability to block current conduction underneath the p-GaN layer. As such, whereas the risk of current crowding may be reduced in such arrangements because of the lack of an active area outside the intended channel area, the deactivated p-GaN portions extending past the active area may present a parasitic leakage path between the source and the drain regions in some examples. Further, the parasitic leakage paths may also impact V_{T} characterization, hence quality and reliability assessment, of a GaN device.

Examples of the present disclosure recognize the foregoing challenges and provide solutions for mitigating current crowding and leakage current issues (collectively referred to as parasitic current issues) in a variety of GaN device configurations using customizable p-GaN layer extensions relative to an active area of a device. For purposes of the present disclosure, a p-GaN layer may be referred to as a III-N gate layer, or a gate layer for short, as will be set forth below with reference to the examples herein. According to some example arrangements, a III-N gate layer comprises a gallium nitride layer including p-type dopants that may be activated, partially activated (or deactivated), or deactivated. For example, a III-N gate layer may include a first portion with activated p-type dopants (e.g., a portion protected or masked from an isolation implant process) and a second portion with deactivated (or partially activated) p-type dopants (e.g., a portion exposed to an isolation implant process).

In some arrangements, one or more gate extensions extending from a portion of the III-N gate layer may be provided proximate to a terminal portion of a source region of a device formed in an active area. In some arrangements, the gate extensions may extend to an isolation region surrounding the active area, where a gate extension may at least partially surround a terminal portion of the source region. In some arrangements, the gate extensions may extend into the isolation region surrounding the active area, past a boundary between the isolation region and the active area. Accordingly, the gate extensions may be configured to effectuate a resistive component operable to block source-drain leakage paths in some examples where the isolation region overlaps at least a portion of the III-N gate layer proximate to the terminal portion of the source region.

In some additional and/or alternative arrangements where the III-N gate layer is contained within the active area, a gate extension may be configured (e.g., placed, laid out, etc.) to block current crowding by suppressing parasitic current pathways that may be developed in extra channel areas under the III-N gate layer extending past the source and drain regions. Further, the formation of gate extensions may be implemented in combination with various source/drain contact designs (e.g., continuous contact design, multi-contact design, hybrid-contact design, etc.), where different configurations of gate extensions may be provided relative to the terminal portions of source/drain regions in a device layout. Whereas the examples herein may provide various structures, materials and processes that may engender these and other beneficial effects, no particular result is a requirement unless explicitly recited in a particular claim.

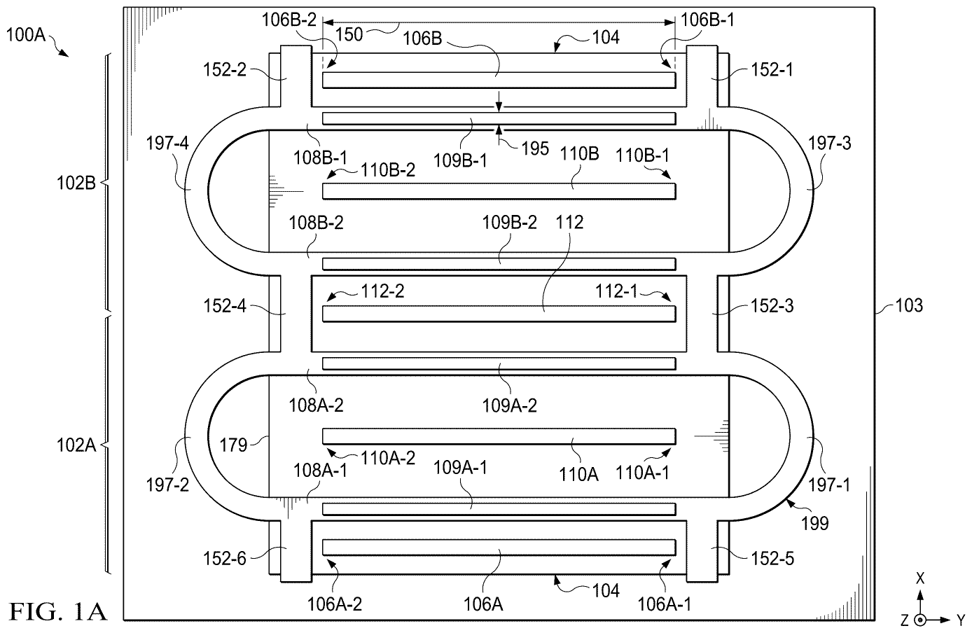

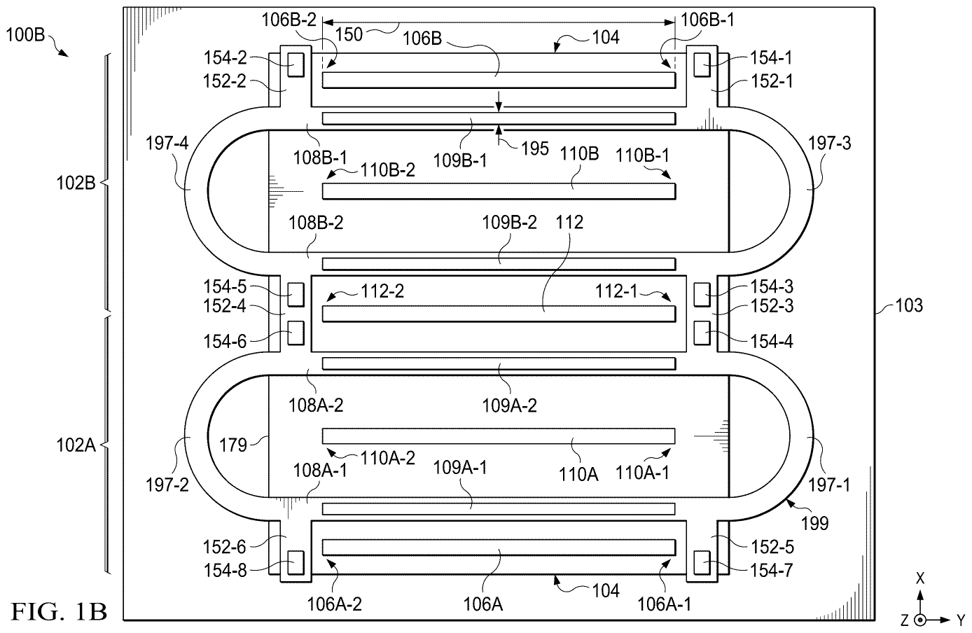

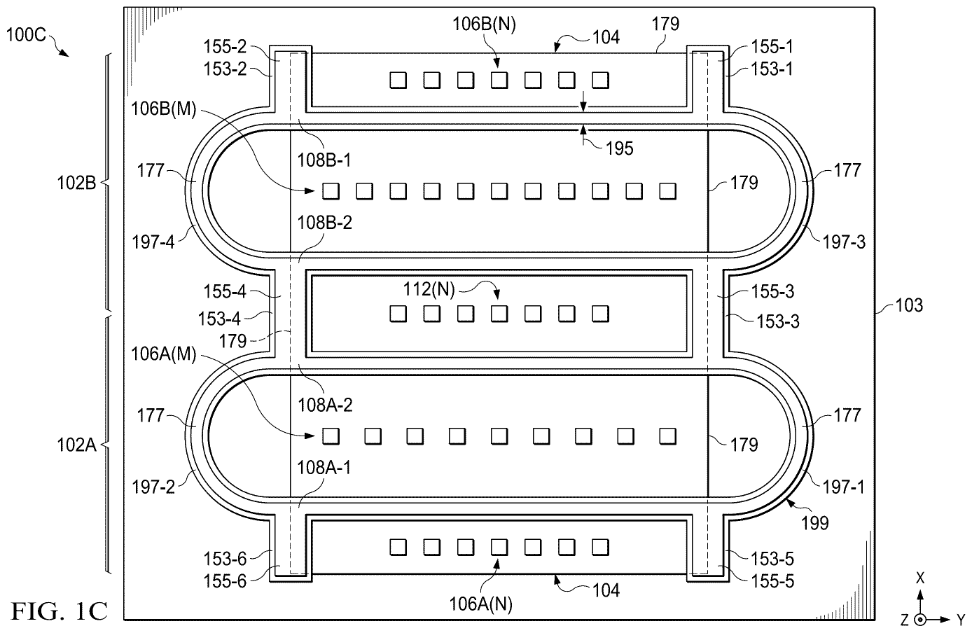

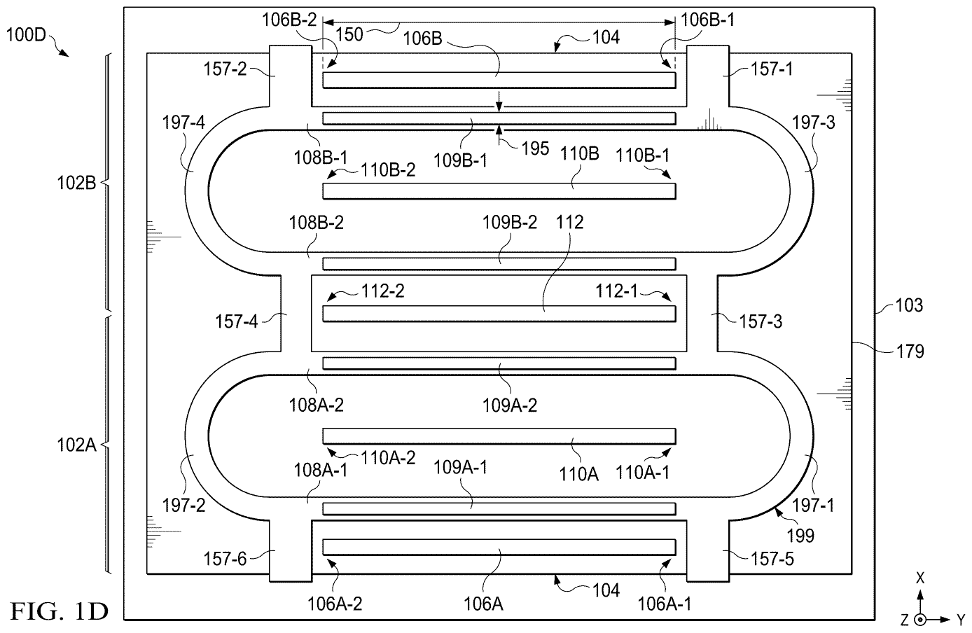

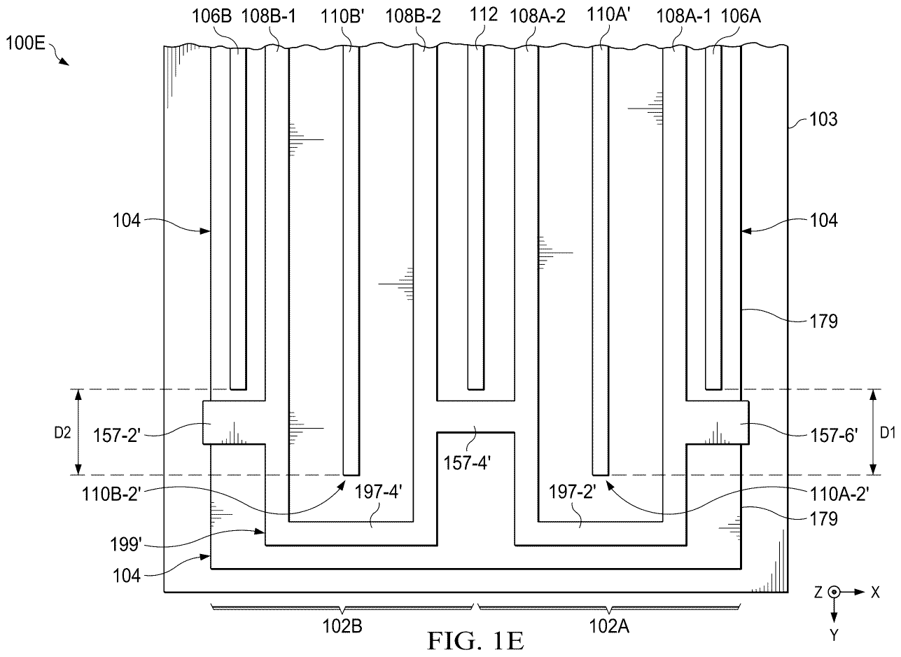

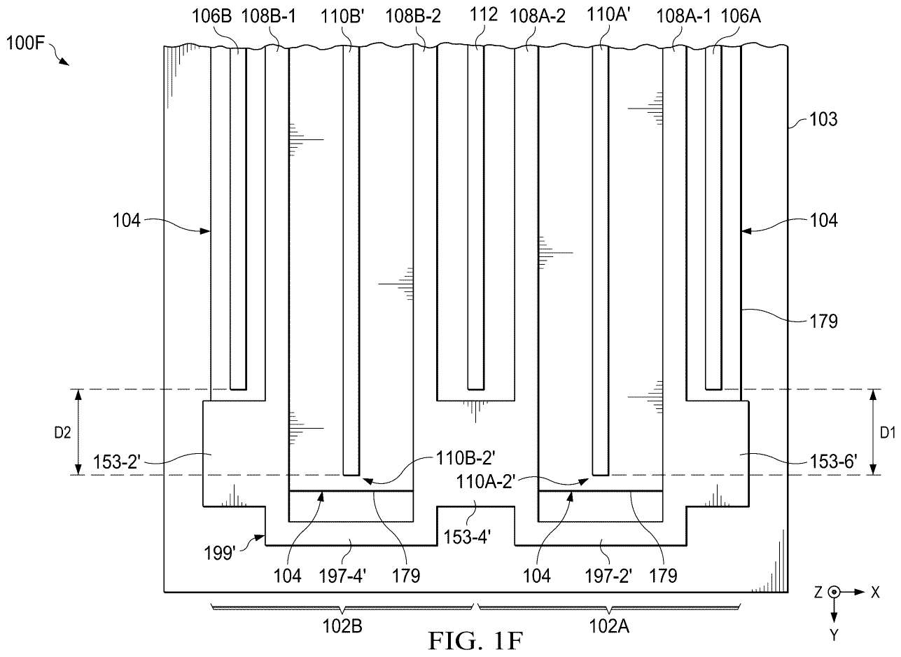

Referring to the drawings, FIGS. 1A-1F depict layouts of representative GaN devices or portions thereof where one or more gate extensions may be provided for suppressing undesirable current paths, also referred to as parasitic current paths, according to some examples of the present disclosure. In some examples, undesirable current paths may comprise leakage paths that may be developed in a device due to deactivated (or partially activated) gate layer portions extending outside an active area of the device. In some examples, undesirable current paths may comprise current paths giving rise to current crowding via unintended channel areas that are attributable to a gate layer contained entirely within the active area of the device. For purposes of the present disclosure, the terms “isolation boundary” and “active area boundary” may be used interchangeably, and may be defined as an interface that demarcates an isolation region, e.g., a region implanted with suitable implant species, from an active area that is not implanted with an isolation implant species. As will be set forth further below, isolation implant species may include species such as argon, silicon, fluorine, nitrogen, etc. in some arrangements. Additionally, an isolation region may be regarded as a region where the crystallinity of the heterojunction structure of a device is damaged or destroyed. Conversely, an active area or region of a device may be regarded as an area where the crystallinity of the heterojunction structure is preserved, thus facilitating the formation of a channel (e.g., 2DEG).

Without limitation, a drain-centered two-finger layout of a GaN device 100A is shown in FIG. 1A, where a first III-N transistor 102A (also referred to as a first device finger) and a second III-N transistor 102B (also referred to as a second device finger) are formed in or over an active area or region 104 surrounded by an isolation area or region 103. As illustrated, an isolation boundary 179 demarcates the active area 104 from the isolation region 103. In some examples, the active area 104 may be formed as part of a common III-N epi stack layer including a heterojunction structure configured to support multiple GaN devices separated by isolation regions in a semiconductor device, although it is not a requirement for purposes of the examples herein. As a drain-centered design, an example III-N transistor or device finger (or, simply “finger” in some examples) may include a source disposed in a source region, a drain disposed in a drain region, and a gate disposed in a gate region between the source and drain regions, where a III-N gate layer may be patterned to form a racetrack or obround structure surrounding the drain region. Accordingly, the source region, the gate region and the drain region of the III-N transistor may extend parallel to one another in the active area of the device. Further, the racetrack structure of the gate layer may comprise a first portion (e.g., a rectilinear portion) and a second portion (e.g., a rectilinear portion) that are coupled to each other by a suitable gate section at each end to form a closed-loop structure. In a two-finger configuration, two III-N transistors may share a common source region disposed between two corresponding racetrack gate layer structures. As will be set forth below, the two racetrack gate layer structures of the two III-N transistors may be coupled to each other near the terminal portions of the common source region using respective gate bridge portions having a suitable form factor for purposes of some examples herein.

By way of illustration, the first III-N transistor 102A includes a drain 110A, a source 106A, and a source 112 common to the first and second III-N transistors 102A and 102B. In similar fashion, the second III-N transistor includes a drain 110B, a source 106B and the common source 112. A gate layer 199 may be patterned to include rectilinear gate portions 108A-1 and 108A-2 with respect to the first III-N transistor 102A and rectilinear gate portions 108B-1 and 108B-2 with respect to the second III-N transistor 102B. For purposes of some examples, the rectilinear gate portions 108A-1/108A-2 and 108B-1/108B-2 may be referred to as first, second, third, or fourth gate portions without being indicative of any specific order, sequence or correspondence with a particular gate portion unless otherwise noted. Although the sources 106A, 106B, drains 110A, 110B and common source 112 are shown as respective continuous contacts, it is not a requirement. Furthermore, whereas the sources 106A/106B, drains 110A/110B, common source 112 as well as the rectilinear gate portions 108A-1/108A-2 and 108B-1/108B-2 of the semiconductor device 100A are disposed in respective source regions, drain regions, common source region and gate regions of the active area 104, such regions are not specifically shown in the Figures for the sake of clarity.

In some implementations, the gate portions 108A-1 and 108A-2 as well as the gate portions 108B-1 and 108B-2 may be coupled to each other by respective gate sections 197-1 to 197-4, e.g., having an arcuate shape, for forming a closed-loop with respect to each III-N transistor 102A, 102B. In this manner, the gate layer 199 may form the closed-loop racetrack structure surrounding a respective drain 110A, 110B. For purposes some examples, the gate sections 197-1 to 197-4 may be referred to as first, second, third, or fourth gate sections without being indicative of any specific order, sequence or correspondence with a particular gate section unless otherwise noted.

In the example of FIG. 1A, III-N transistors 102A and 102B are disposed in respective portions of the active area 104 (e.g., a first portion and a second portion, not specifically shown in FIG. 1A). With respect to the first III-N transistor 102A, a corresponding portion of the active area 104 may be regarded as being inclusive of various regions as follows: a first source region having the source 106A, a first drain region having the drain 110A, and a first gate region having the gate portion 108A-1, where the first gate region is disposed on a first side of the first drain region. As previously noted, the first source, first drain and first gate regions may extend parallel to one another, e.g., along the Y-axis.

In similar fashion, a corresponding portion of the active area 104 with respect to the second III-N transistor 102B may be regarded being inclusive of various regions as follows: a second source region having the source 106B, a second drain region having the drain 110B, and a second gate region having the gate portion 108B-1, where the second gate region is disposed on a first side of the second drain region. Further, the second source, second drain and second gate regions may extend parallel to one another, e.g., along the Y-axis.

Because of the nature of the closed-loop configuration of the gate layer 199, the first III-N transistor 102A also includes a third gate portion 108A-2 disposed in a third gate region disposed in a second side (e.g., opposite to the first side) of the first drain region that includes the first drain 110A. In similar manner, the second III-N transistor 102B also includes a fourth gate portion 108B-2 disposed in a fourth gate region disposed in a second side (e.g., opposite to the first side) of the second drain region that includes the second drain 110B.

In the example of FIG. 1A, the isolation boundary 179 is depicted as extending across the curvilinear gate sections 197-1 to 197-4, e.g., to suppress current crowding. Accordingly, the curvilinear gate sections 197-1 to 197-4 comprise deactivated (or weakly activated) portions of the gate layer 199. In some additional and/or alternative arrangements, the gate layer 199 of the two-finger GaN device 100A may lie entirely within the active area 104 as will be set forth further below. Regardless of how a III-N gate layer is laid out in a particular design, the gate layer 199 may be provided with one or more segments, tabs, extensions, components, etc., collectively referred to as gate extensions herein. Such gate extensions may extend to (or partially into) the isolation region 103 at appropriate locations of the GaN device 100A for blocking the formation of undesirable current paths as will be set forth below.

In some arrangements, gate contacts or electrodes having a continuous contact design may be formed with respect to each III-N transistor 102A, 102B, where a gate contact may have a width 150 based on the width of the III-N transistors 102A, 102B and a length 195. As illustrated, gate contacts 109A-1 and 109A-2 are coupled to the gate portions 108A-1 and 108B-2, respectively, with respect to the first III-N transistor 102A. Likewise, gate contacts 109B-1 and 109B-2 are coupled to the gate portions 108B-1 and 108B-2, respectively, with respect to the second III-N transistor 102B. To suppress source/drain leakage current paths near the isolation boundary 179 proximate to (e.g., underneath) the gate sections 197-1 to 197-4 that are deactivated by an isolation implant, the gate layer 199 of the GaN device 100A includes gate extensions 152-1 to 152-6 at various suitable locations. For example, the gate extensions 152-1 to 152-6 may be provided proximate to terminal portions of respective sources (e.g., source contacts or source regions) of the GaN device 100A. In this manner, a gate extension may block a parasitic current path between a source terminal portion and an adjacent drain terminal portion—e.g., providing a high-resistance region therebetween in view of the gate extension depleting 2DEG under the gate extension.

By way of illustration, the gate extension 152-1 extending from the gate portion 108B-1 to (or partially into) the isolation region 103 is formed as an extension proximate to a terminal portion 106B-1 associated with the source 106B (which may be referred to as a source terminal portion), which is disposed in corresponding source region as noted previously. The gate extension 152-1 is operable to block leakage current paths (e.g., by depleting 2DEG under the gate extension 152-1) between the source terminal portion 106B-1 and a corresponding adjacent terminal portion 110B-1 associated with the drain 110B (which may be referred to as a drain terminal portion) of the III-N transistor 102B. In similar fashion, the gate extension 152-2 is formed as an extension from the gate portion 108B-1 proximate to a source terminal portion 106B-2 for blocking leakage current paths between the source terminal portion 106B-2 and a corresponding adjacent drain terminal portion 110B-2 of the III-N transistor 102B. Likewise, the gate extensions 152-5 and 152-6 extending to (or partially into) the isolation region 103 may be formed with respect to the III-N transistor 102A for suppressing leakage current paths between respective terminal portions 106A-1, 106A-2 associated with the source 106A and corresponding adjacent terminal portions 110A-1, 110A-2 associated with the drain 110A.

With respect to suppressing leakage current paths between the common source 112 and the drains 110A and/or 110B, some examples may provide gate extensions 152-3 and 152-4, also referred to herein as bridge portions, extending between the gate portions 108A-2 and 108B-2. In this manner, each bridge portion surrounds and electrically isolates a respective terminal portion 112-1, 112-2 associated with the common source 112—e.g., providing a high-resistance region near the respective terminal portions in view of the bridge portions depleting 2DEG under the bridge portions.

Depending on implementation, the shape and/or size of gate extensions according to the examples herein may vary in a number of ways as long as a source terminal portion of a GaN device is blocked by a gate extension of suitable shape and/or size where the gate extension extends to or overlaps at least an edge of the active area (e.g., an isolation boundary) proximate to the source terminal portion. For purposes of the present disclosure, a source terminal portion (or a source region terminal portion) may refer to or comprise a terminal portion of a source contact and/or a terminal portion of a source region that includes a source contact. In similar manner, a drain terminal portion (or a drain region terminal portion) may refer to or comprise a terminal portion of a drain contact and/or a terminal portion of a drain region that includes a drain contact.

For example, the gate extension 152-1 is depicted in FIG. 1A as a rectangular extension with respect to the source region terminal portion 106B-1 that extends at least all the way to (or across) the isolation boundary 179 along a first direction (e.g., aligned to the X-axis) of the device layout but not to the isolation boundary 179 along a second direction (e.g., aligned to the Y-axis) orthogonal to the first direction. In some examples, the gate extension 152-1 may have a regular quadrilateral shape (e.g., a square) that may extend in both directions and overlap or coincide with the isolation boundary 179 along both the X-and Y-axes in order to provide more robust blocking capability. In general, the larger a gate extension, the greater is the capability to block or suppress parasitic current paths associated with a source region terminal portion (or a drain region terminal portion)—e.g., having a greater region with 2DEG depleted.

In similar manner, the gate extensions 152-2, 152-5 and 152-6 may extend to the isolation boundary 179 proximate to the terminal portions 106B-2 (associated with the source 106B) and 106A-1 and 106A-2 (associated with the source 106A), respectively. Further, the gate extensions, i.e., bridge portions 152-3 and 152-4, surrounding terminal portions 112-1 and 112-2 associated with the common source 112, respectively, may also be extended (e.g., along Y-direction) to overlap the isolation boundary 179 in some arrangements. In general, the size and/or shape of III-N gate extensions may vary as long as each extension has an appropriate size and/or shape extending to and/or overlapping an isolation boundary without violating applicable critical dimension (CD) design rules.

In some additional and/or alternative arrangements, one or more gate extensions 152-1 to 152-6 may be provided with or coupled to suitable contact structures, e.g., gate contacts or electrodes. Accordingly, more robust blocking capability may be obtained in a GaN device by providing additional gate control. In some additional and/or alternative arrangements, source and drain regions of a GaN device may be provided with a multiple contact or multi-contact design instead of a continuous contact design as shown in FIG. 1A. In still further arrangements, the entire gate layer of a GaN device may be enclosed within the active area of the GaN device such that there is no gate portion or section exposed to isolation implant. Accordingly, in such arrangements, the gate layer may not include any deactivated gate portions or sections. Set forth below is a description of examples with respect to some of the foregoing variations for purposes of the present disclosure.

FIG. 1B depicts an example two-finger layout of a GaN device 100B where each gate extension is coupled to with at least one extra gate contact, respectively, in addition to the gate contacts associated with respective III-N transistors of the GaN device 100B. As illustrated, the GaN device 100B is identical to the GaN device 100A shown in FIG. 1A except for the additional gate contacts provided in the gate extensions 152-1 to 152-6. Accordingly, the description of the GaN device 100A set forth above is also applicable to the GaN device 100B except as otherwise noted herein. In addition to the gate contacts 109A-1, 109A-2 associated with the III-N transistor 102A and the gate contacts 109B-1 and 109B-2 associated with the III-N transistor 102B, gate contacts 154-1, 154-2, 154-7 and 154-8 are coupled to the gate extensions 152-1, 152-2, 152-5 and 152-6, respectively. Further, the bridge portions 152-3, 152-4 provided to block parasitic current paths associated with the common source 112 may each have one or more additional gate contacts in an example arrangement while satisfying applicable CD design rules. As shown in the example of FIG. 1B, the bridge portion 152-3 is coupled to two gate contacts 154-3 and 154-4 and the bridge portion 152-4 is coupled to two contacts 154-5 and 154-6.

FIG. 1C depicts an example two-finger layout of a GaN device 100C including a multi-contact design for the source and drain, respectively, where enlarged gate extensions may overlap an isolation boundary and at least partially extend over an isolation region at respective locations. Further, a continuous gate contact structure having gate contact extensions coupled to corresponding gate extensions is also illustrated in FIG. 1C with respect to the GaN device 100C. As depicted, the GaN device 100C is similar to the GaN device 100A shown in FIG. 1A except as noted herein. Accordingly, the description of the GaN device 100A set forth above is also applicable to the GaN device 100C, with appropriate changes as described below. By way of illustration, the III-N transistors 102A, 102B are each provided with a respective plurality of source contacts, 106A(N), 106B(N), and a respective plurality of drain contacts 110A(M) and 110B(M). In similar fashion, the GaN device 100C may include a plurality of common source contacts 112(N) in some arrangements. Although the drain contacts of a III-N transistor may be disposed in a drain region extending past a source region having corresponding source contacts by a distance in an example layout, it is not a requirement. Further, the drain contacts (e.g., drain contacts 110A(M)) and the source contacts (e.g., source contacts 106A(N)) may comprise different numbers of contacts and may be arranged in various ways depending on implementation, including in combination with continuous contact designs in some arrangements.

Similar to the gate extensions 152-1 to 152-6 shown in FIG. 1B, the GaN device 100C illustrated in FIG. 1C includes gate extensions 153-1 to 153-6 extending from different gate portions of the gate layer 199, except the gate extensions 153-1 to 153-6 are enlarged to extend past the isolation boundary 179 at appropriate locations in relation to the source contacts 106B(N), 112(N) and 106A(N). Further, a closed-loop continuous gate contact structure 177 includes gate contact extensions 155-1 to 155-6 coupled to respective gate extensions 153-1 to 153-6 in an example arrangement.

FIG. 1D depicts an example two-finger layout of a GaN device 100D where a III-N gate layer is enclosed within an isolation boundary except where gate extensions may be extended to overlap an isolation boundary at appropriate locations according to the examples herein. As shown in the example of FIG. 1D, which is similar to the example of FIG. 1A except as noted herein, the gate layer 199 including the curvilinear gate sections 197-1 to 197-4 is surrounded by the isolation boundary 179. In some arrangements, gate extensions 157-1 to 157-6 similar to the gate extensions 152-1 to 152-6 may be provided at appropriate locations relative to the source region terminal portions as described previously. As such, there may be no leakage current paths when the GaN device 100D is off because there are no gate portions deactivated by the isolation implant that are proximate to the source region terminal portions. Nevertheless, the gate extensions 157-1 to 157-6 are operable to block current crowding at the drain region terminal portions when the GaN device 100D is in certain operating conditions, e.g., the gate is turned on using a threshold voltage sufficient to establish an intended channel area directly between the source and drain regions (e.g., across a channel length along the X-axis) but insufficient to create extra channel areas near the source region terminal portions.

FIGS. 1E and 1F depict partial layouts of GaN devices 100E, 100F, respectively, in a two-finger device configuration similar to some of the foregoing examples. Similar to the example of FIG. 1D where the III-N gate layer 199 is contained within the active area 104, the example of FIG. 1E depicts a III-N gate layer 199′ that is also contained within the active area 104, except for a boxed end gate section configuration as noted herein. For example, gate sections 197-2′ and 197-4′ that connect rectilinear gate portions 108A-1 and 108A-2 and rectilinear gate portions 108B-1 and 108B-2 are depicted as rectangular boxed end structures rather than curvilinear sections 197-2 and 197-4 shown in FIG. 1D. Further, drains 110A′ and 110B′ of the GaN device 100E extend past corresponding sources 106A and 106B as well as the common contact 112 by a suitable distance in contrast to the GaN device 100D. For example, the drain 110A′ of the first III-N transistor 102A of the GaN device 100E extends past the source 106A of the first III-N transistor 102A by a distance D1. Likewise, the drain 110B′ of the second III-N transistor 102B of the GaN device 100E extends past the source 106B of the second III-N transistor by a distance D2, which may be the same as or different from D1.

Similar to the GaN device 100D, the GaN device 100E also includes gate extensions 157-6′ and 157-2′ that extend to (or across) the isolation boundary 179 from the rectilinear gate portions 108A-1 and 108B-1, respectively. Likewise, the GaN device 100E also includes the bridge portion 157-4′ disposed between the rectilinear gate portions 108A-2 and 108B-2. Accordingly, current crowding near drain region terminal portions 110A-2′ and 110B-2′ is mitigated in the GaN device 100E similar to the GaN device 100D. Although no gate electrodes or gate electrode extensions are illustrated in the example of FIG. 1E for the sake of clarity, the GaN device 100E may include gate electrodes coupled to the rectilinear gate portions 108A-1/108A-2 and 108B-1/108B-2 as well gate electrode extensions coupled to gate extensions 157-6′ and 157-2′ and the bridge portion 157-4′ of the gate layer 199′. In some arrangements, the gate extensions 157-2′ and 157-6′ may be extended along the Y-axis such that they form a single piece coterminous with the boxed end gate sections 197-4′ and 197-2′.

The GaN device 100F shown in FIG. 1F is similar to some of the examples set forth above where at least a portion of a gate layer may be disposed outside the active area. For example, gate sections 197-2′ and 197-4′ that connect rectilinear gate portions 108A-1 and 108A-2 and rectilinear gate portions 108B-1 and 108B-2, respectively, are depicted as rectangular boxed end structures that extend over the isolation region 103 similar to the curvilinear sections 197-2 and 197-4 shown in FIGS. 1A-1C, for instance. On the other hand, drains 110A′ and 110B′ of the GaN device 100F are depicted as extending past corresponding sources 106A and 106B as well as the common contact 112 by a suitable distance, e.g., distance D1 and distance D2, similar to the example of FIG. 1E. The gate layer 199′ of the GaN device 100F includes gate extensions 153-2′ and 153-6′ and the bridge portion 153-4′ that extend past the isolation boundary 179 similar to the example shown in FIG. 1C. Accordingly, the risk of parasitic leakage paths between the source and drain regions due to the deactivated (or weakly activated) gate portions in the isolation region 103 may be mitigated by the gate extensions 153-2′ and 153-6′ and the bridge portion 153-4′ in a similar manner.

Moreover, the gate extensions 153-2′ and 153-6′ and the bridge portion 153-4′ are also operable to mitigate current crowding near the drain region terminal portions 110A-2′ and 110B-2′ in the GaN device 100F similar to the GaN device 100E. Although no gate electrodes or gate electrode extensions are illustrated in the example of FIG. 1F for the sake of clarity, the GaN device 100F may include gate electrodes coupled to the rectilinear gate portions 108A-1/108A-2 and 108B-1/108B-2 as well as gate electrode extensions coupled to the gate extensions 153-2′ and 153-6′ and the bridge portion 153-4′ of the gate layer 199′.

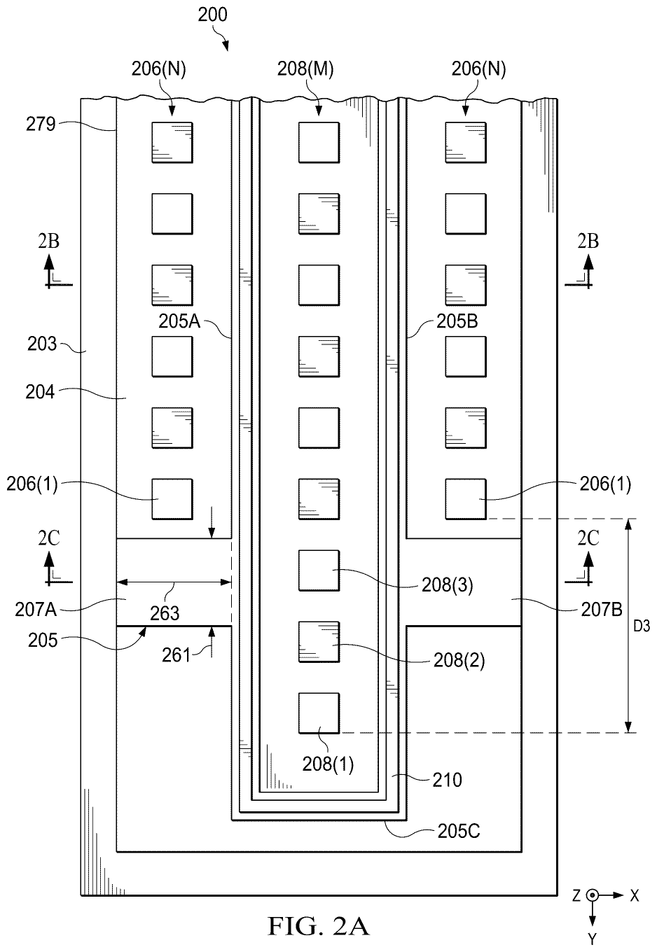

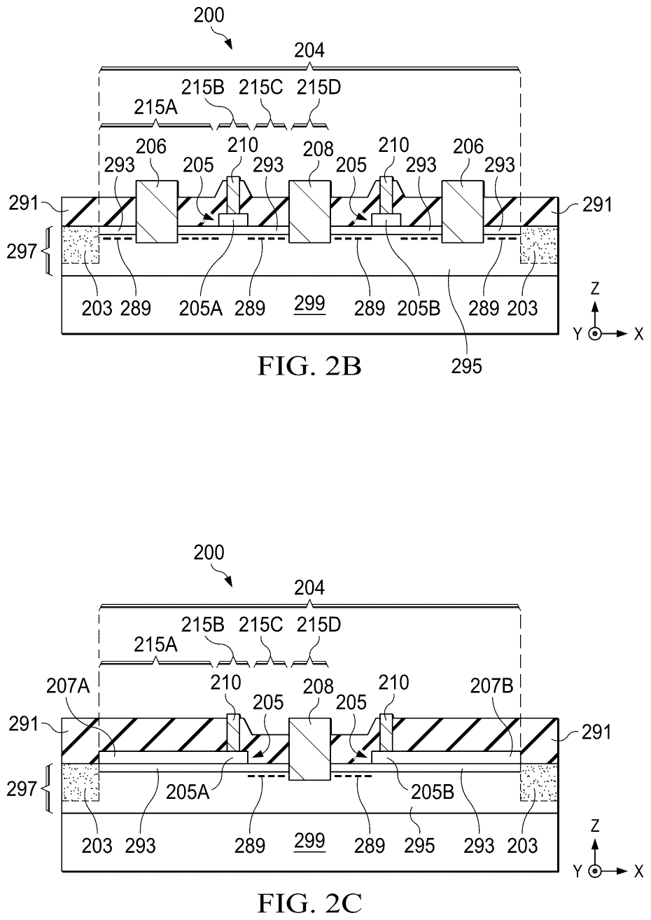

FIG. 2A depicts a partial layout of a GaN device in a single-finger configuration including one or more gate extensions for mitigating parasitic current issues according to some further examples of the present disclosure. As illustrated, an example drain-centered GaN device 200 may include an active area 204 surrounded by an isolation region 203, with an isolation boundary 279 disposed between the active area 204 and the isolation region 203. The active area 204 includes a closed-loop III-N gate layer 205 disposed in a gate region (not shown in FIG. 2A), where the gate layer 205 comprises rectilinear gate portions 205A, 205B joined by an end cap portion 205C. A plurality of drain contacts 208(M) are disposed in a drain region (not shown in FIG. 2A) surrounded by the closed-loop gate layer 205. A respective plurality of source contacts 206(N) are disposed in corresponding source regions (not shown in FIG. 2A) that extend parallel to the corresponding rectilinear gate portion 205A, 205B (e.g., along the Y-axis).

By way of example, a continuous gate contact or electrode 210 coupled to the gate layer 205 is shown in FIG. 2A. Whereas the drain contacts 208(M) extend past the source contacts 206(N) provided along the either side of the rectilinear gate portion 205A, 205B, e.g., by a distance D3, respectively, it is not a requirement as noted previously. To suppress unwanted current crowding paths between a source region terminal portion including a source contact, e.g., source contact 206(1), and drain region terminal portion including a drain contact, e.g., drain contacts 208(1)-208(3) disposed beyond the terminal source contact 206(1), a gate extension 207A, 207B is provided proximate to the respective source region terminal portions. In some arrangements, the gate extensions 207A, 207B may comprise rectangular tab structures that extend to the isolation region 203, e.g., coterminous with the isolation boundary 279. In some arrangements. The gate extensions 207A, 207B may extend beyond the isolation boundary 279, e.g., extend across or over at least a portion of the isolation region 203. Whereas the gate extensions 207A, 207B are illustrated as having identical form factors, e.g., each having a length 263 (e.g., along the X-axis) and a width 261 (e.g., along the Y-axis), it is not a requirement. Furthermore, the gate extensions 207A, 207B may be extended along and past the end cap portion 205C of the gate layer 205 such that they form a single boxed-end shaped gate extension that extends to (or partially into) the isolation region 203 in both X-and Y-directions in some arrangements. As previously noted, the gate extensions 207A, 207B may be provided in various spatial configurations, separately or as a single extension structure, for purposes of some examples herein.

Although a multiple contact design is illustrated in the example of FIG. 2A with respect to the source and drain contacts 206(N), 208(M), respectively, where the drain contacts 208(M) extend beyond the source contacts 206(N), it is not a requirement as previously noted. Further, instead of having a continuous gate contact 210 as shown in FIG. 2A, some examples may include multiple gate contacts coupled to the gate layer 205 at specific locations, e.g., in the end cap portion 205C. Moreover, some examples may include gate contacts or gate contact extensions coupled to the gate extensions 207A, 207B as described previously. Additional and/or alternative contact layout configurations that may be combined with examples of gate extensions according to the teachings herein may be found in the U.S. Patent Application Publication 2022/0231156, which is incorporated by reference herein in its entirety for all purposes.

FIG. 2B depicts a cross-sectional view of a GaN device corresponding to the layout of the GaN device 200 shown in FIG. 2A along a sectional plane through the rectilinear portions 205A, 205B of the gate layer 205 that do not include gate extensions. FIG. 2C depicts a cross-sectional view of the GaN 200 device along a sectional plane through the gate extensions 207A, 207B configured to suppress parasitic current crowding paths as described above. Taking FIGS. 2A-2C together, additional details with respect to the GaN device 200 including the gate extensions 207A, 207B are set forth below according to some examples.

As depicted in FIGS. 2B and 2C, the GaN device 200 is formed on a portion of a semiconductor substrate 299, which may be provided as a silicon wafer, a silicon-on-sapphire wafer, or a silicon carbide wafer, and/or as a semiconductor substrate including cores configured for matching coefficient of thermal expansion (CTE), and/or the like. A buffer layer 295 is formed on the substrate 299 and may comprise one or more layers of III-N semiconductor material. In some examples where the substrate 299 is implemented as a silicon wafer or a sapphire wafer, the buffer layer 295 may include a nucleation layer having a stoichiometry that includes aluminum to match a lattice constant of the substrate 299. In some examples, the buffer layer 295 may further include layers/sublayers of aluminum gallium nitride (AlGaN) with decreasing aluminum content, including an unintentionally doped (UID) GaN sublayer in some arrangements. For purposes of the examples herein, the various layers/sublayers of a buffer layer, e.g., the buffer layer 295, are not specifically shown in FIGS. 2B and 2C.

Depending on implementation, the buffer layer 295 may have a thickness of about 1 micron (μm) to several microns, e.g., 3.5 μm to 7.0 μm, which may be formed by a suitable epitaxial process, e.g., a metal organic vapor phase epitaxy (MOVPE) process (also known as organometallic vapor phase epitaxy (OMVPE) or metalorganic chemical vapor deposition (MOCVD)), where several sequential steps may be performed to form the various constituent layers and/or sublayers. In some arrangements, an example buffer layer 295 may therefore comprise a stack of multiple layers/sublayers of suitable materials and compositions (e.g., GaN, AlGaN, etc.) as noted above, where the layers/sublayers may have variable thicknesses depending on the technology and device application. In some arrangements, the buffer layer 295 may include AlGaN-based transition layers, epitaxial layers with strain-layer superlattice (SLS) structures, and the like.

The buffer layer 295 may be formed over an area of the substrate 299, where different regions such as a source region, a gate region, a drain region and a drain access region between the gate region and the drain region may be provided with respect to the GaN device 200. Because of the symmetrical nature of the drain-centered design, gate regions and source regions may be provided on either side of a common drain region of the GaN device 200. As depicted, a source region 215A, a gate region 215B, a common drain region 215D and a drain access region 215C are specifically illustrated with respect to one side of the GaN device 200, where corresponding regions are also provided on the other side of the common drain region 215D. The source region 215A may be regarded as including a source access region (not specifically shown in FIGS. 2B-2C), which may refer to a region between a source contact or a group of source contacts (e.g., source contacts 206) and the gate region 215B similar to the drain access region 215C. A channel layer may be provided as part of the buffer layer 295—e.g., a top portion of the buffer layer 295 proximate to a barrier layer 293. Whereas a channel layer may primarily include GaN material, there may be optional trace amounts of other group III elements, such as aluminum or indium, in some implementations.

A barrier layer 293 comprising III-N semiconductor material is formed over the buffer layer 295 in a suitable epitaxy process. In an example arrangement, the barrier layer 293 may have a thickness ranging from about 1 nanometer (nm) to about 60 nm, and may include aluminum and nitrogen. In some versions of this example, the barrier layer 293 may include gallium at a lower atomic percent than aluminum. In some versions, the barrier layer 293 may also include indium. In some examples, the barrier layer 293 includes an AlGaN layer.

The barrier layer 293 over the buffer layer 295 is operable as part of a heterojunction structure 297 for causing the formation of a 2DEG (e.g., 2DEG 289 shown in FIGS. 2B and 2C) proximate to an interface between the barrier layer 293 and the buffer layer 295. In some examples, the stoichiometry and thickness of the barrier layer 293 may be configured to provide a suitable free charge carrier density (e.g., 3×10¹² cm⁻² to 2×10¹³ cm⁻²) of the 2DEG for facilitating the device operation.

For purposes of effectuating EMODE functionality, a patterned p-doped III-N layer, e.g., the gate layer 205, is formed over the barrier layer 293 in the gate region 215B as shown in FIG. 2B. In some examples, the gate layer 205 may comprise one or more layers of III-N material, and may also be referred to as a p-III-N layer or a p-GaN layer as previously noted. In some examples, the gate layer 205 may include a p-dopant concentration (e.g., Mg) of about 1×10¹⁷ atoms/cm³ to 1×10²¹ atoms/cm³ and may have a thickness of about 10 nm to 200 nm. As a result of patterning the gate layer 205 (e.g., removing portions of the gate layer 205 outside the gate region 215B), the 2DEG 289 may be established in the channel layer outside the gate region 215B.

In some additional and/or alterative arrangements, additional layers such as an AlGaN cap layer of about 4 nm to 10 nm (e.g., devoid of p-doping) and/or a low-pressure chemical vapor deposition (LPCVD) silicon nitride (SiN) cap layer of about 10 nm to 20 nm, which are not specifically shown in FIGS. 2A-2C, may be optionally provided over the gate layer 205.

A suitable device isolation step may be implemented to provide an isolation region with respect to the GaN device 200. Depending on implementation, an isolation step may include implanting with appropriate implant species to define a region, e.g., isolation region 203, where the crystallinity of the heterojunction structure 297 in the isolation region 203 is damaged or otherwise compromised, resulting in increased resistance. Accordingly, the 2DEG 289 is absent, eliminated or otherwise disrupted in the isolation region 203 that surrounds the active area 204 of the GaN device 200. In some examples, an argon implant having an energy of between 100 kilo-electron volts (keV) and 300 keV with an implant dose of 1×10¹⁴ ions/cm² to 1×10¹⁶ ions/cm² may be implemented to achieve device isolation. Other implant species such as silicon, fluorine, nitrogen, etc., may be also used as isolation implant species in additional and/or alternative examples.

As illustrated in FIGS. 2B and 2C, a dielectric layer stack 291 including one or more dielectric layers are also formed over the heterojunction structure 297. Depending on implementation, the dielectric layer stack 291 may include one or more SiN layers formed by LPCVD/PECVD processes, where some of the layers may operate as surface passivation layers. In some additional and/or alternative arrangements, the dielectric layer stack 291 may comprise different materials, e.g., silicon dioxide (SiO₂), silicon oxynitride (SiON), aluminum oxide (Al₂O₃), etc., and may be formed using other techniques such as ALD. Source contacts 206, drain contacts 208 and gate contact 210 of the GaN device 200 may be formed in a gate first flow (e.g., where the source/drain contacts are formed after forming a gate stack) or in a gate last flow (e.g., where the source/drain contacts are formed before forming a gate stack).

During the formation of the gate layer 205, the rectilinear gate portions 205A, 205B as well as the end cap portion 205C may be patterned appropriately in order to form a closed-loop structure, where the rectilinear gate portions 205A, 205B are operable as part of a gate stack for effectuating EMODE device functionality as described previously. According to the examples herein, patterning of the gate layer 205 may also include forming the gate extensions 207B, 207B that extend to the isolation region 203 as shown in FIGS. 2A and 2C, where the gate extensions 207A, 207B are disposed proximate to the source region terminal portions, e.g., including source contacts 206(1). Whereas gate extensions 207A, 207B may be devoid of contact structures in some arrangements (e.g., as shown in FIGS. 2A and 2C), additional and/or alternative arrangements may include supplementary or extra contact structures, e.g., gate contacts, gate contact extensions, etc., coupled to the gate extensions 207A, 207B.

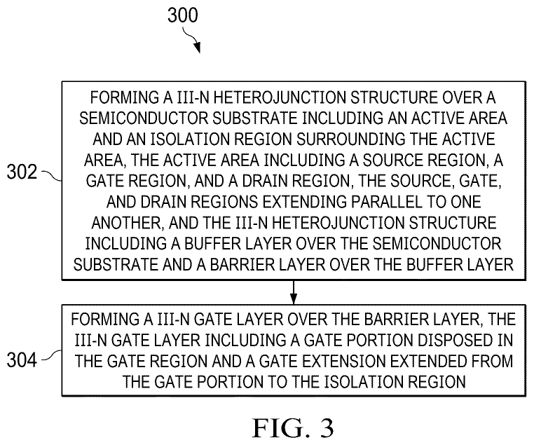

FIG. 3 is a flowchart of a method 300 of fabricating a semiconductor device including a GaN device according to some examples of the present disclosure. In one arrangement, the method 300 may commence with forming a III-N heterojunction structure over a semiconductor substrate including an active area and an isolation region surrounding the active area, where the active area includes a source region, a gate region, and a drain region, as set forth at block 302. As previously stated, the source, gate, and drain regions extend parallel to one another. Further, the III-N heterojunction structure includes a buffer layer over the semiconductor substrate and a barrier layer over the buffer layer. At block 304, a III-N gate layer is formed over the barrier layer, the III-N gate layer including a gate portion disposed in the gate region and a gate extension extended from the gate portion to the isolation region. In an example arrangement, the gate extension is disposed proximate to a terminal portion of the source region.

While various examples of the present disclosure have been described above, they have been presented by way of example only and not limitation. Numerous changes to the disclosed examples can be made in accordance with the disclosure herein without departing from the spirit or scope of the disclosure. Thus, the breadth and scope of the present disclosure should not be limited by any of the above described examples. Rather, the scope of the disclosure should be defined in accordance with the claims appended hereto and their equivalents.

For example, in this disclosure and the claims that follow, unless stated otherwise and/or specified to the contrary, any one or more of the layers set forth herein can be formed in any number of suitable ways, such as with spin-on techniques, sputtering techniques (e.g., Magnetron and/or ion beam sputtering), (thermal) growth techniques or deposition techniques such as chemical vapor deposition (CVD), physical vapor deposition (PVD), low pressure CVD (LPCVD), plasma enhanced CVD (PECVD), or atomic layer deposition (ALD), etc. As another example, silicon nitride may be a silicon-rich silicon nitride or an oxygen-rich silicon nitride. Silicon nitride may contain some oxygen, but not so much that the materials dielectric constant is substantially different from that of high purity silicon nitride.

Further, in at least some additional or alternative implementations, the functions/acts described in the blocks may occur out of the order shown in the flowcharts. For example, two blocks shown in succession may in fact be executed substantially concurrently or the blocks may sometimes be executed in the reverse order, depending upon the functionality/acts involved. Moreover, the functionality of a given block of the flowcharts and/or block diagrams may be separated into multiple blocks and/or the functionality of two or more blocks of the flowcharts and/or block diagrams may be at least partially integrated. Also, some blocks in the flowcharts may be optionally omitted. Furthermore, although some of the diagrams include arrows on communication paths to show a primary direction of communication, it is to be understood that communication may occur in the opposite direction relative to the depicted arrows. Finally, other blocks may be added/inserted between the blocks that are illustrated.

The order or sequence of the acts, steps, functions, components or blocks illustrated in any of the flowcharts and/or block diagrams depicted in the drawing Figures of the present disclosure may be modified, altered, replaced, customized or otherwise rearranged within a particular flowchart or block diagram, including deletion or omission of a particular act, step, function, component or block. Moreover, the acts, steps, functions, components or blocks illustrated in a particular flowchart may be inter-mixed or otherwise inter-arranged or rearranged with the acts, steps, functions, components or blocks illustrated in another flowchart in order to effectuate additional variations, modifications and configurations with respect to one or more processes for purposes of practicing the teachings of the present disclosure. Likewise, although various examples have been set forth herein, not all features of a particular example are necessarily limited thereto and/or required therefor.

At least some portions of the foregoing description may include certain directional terminology, such as, “upper”, “lower”, “top”, “bottom”, “left-hand”, “right-hand”, “front side”, “backside”, “vertical”, “horizontal”, etc., which may be used with reference to the orientation of some of the Figures or illustrative elements thereof being described. Because components of some examples can be positioned in a number of different orientations, the directional terminology is used for purposes of illustration and is in no way limiting. Likewise, references to features referred to as “first”, “second”, etc., are not indicative of any specific order, importance, and the like, and such references may be interchanged, depending on the context, implementation, etc. In addition, terms such as “over”, “under”, “below”, etc., relative to the spatial orientation of two components does not necessarily mean that one component is immediately or directly over the other component, or that one component is immediately or directly under or below the other component. Further, the features and/or components of examples described herein may be combined with each other unless specifically noted otherwise.

Although various implementations have been shown and described in detail, the claims are not limited to any particular implementation or example. None of the above Detailed Description should be read as implying that any particular component, element, step, act, or function is essential such that it must be included in the scope of the claims. Where the phrases such as “at least one of A and B” or phrases of similar import are recited or described, such a phrase should be understood to mean “only A, only B, or both A and B.” Reference to an element in the singular is not intended to mean “one and only one” unless explicitly so stated, but rather “one or more.” In similar fashion, phrases such as “a plurality” or “multiple” may mean “one or more” or “at least one”, depending on the context. All structural and functional equivalents to the elements of the above-described implementations are expressly incorporated herein by reference and are intended to be encompassed by the claims appended below.

What is claimed is:

1. A semiconductor device, comprising:
a semiconductor substrate including an active area and an isolation region surrounding the active area, the active area including a source region, a gate region, and a drain region, wherein the source region, the gate region, and the drain region extend parallel to one another;
a III-N heterojunction structure over the semiconductor substrate, the III-N heterojunction structure including a buffer layer over the semiconductor substrate and a barrier layer over the buffer layer; and
a III-N gate layer over the barrier layer, the III-N gate layer including:
a gate portion disposed in the gate region; and
a gate extension extended from the gate portion to the isolation region.

2. The semiconductor device of claim 1, wherein the gate extension is disposed proximate to a terminal portion of the source region.

3. The semiconductor device of claim 1, further comprising:
a gate electrode coupled to the gate portion.

4. The semiconductor device of claim 3, further comprising:
a gate electrode extension extended from the gate electrode and coupled to the gate extension.

5. The semiconductor device of claim 1, wherein the gate portion is a first gate portion, and the III-N gate layer further includes a second gate portion extended from the first gate portion, the first and second gate portions at least partially surround a terminal portion of the drain region.

6. The semiconductor device of claim 5, wherein a section of the second gate portion is disposed over the isolation region and implanted with isolation implant species comprising at least one of argon, silicon, fluorine, and nitrogen.

7. The semiconductor device of claim 5, wherein the second gate portion is disposed over the active area.

8. The semiconductor device of claim 1, wherein the gate extension extends over at least a portion of the isolation region.

9. The semiconductor device of claim 8, wherein a portion of the gate extension is implanted with isolation implant species comprising at least one of argon, silicon, fluorine, and nitrogen.

10. A semiconductor device, comprising:
a semiconductor substrate including an active area and an isolation region surrounding the active area;
a III-N heterojunction structure over the semiconductor substrate, the III-N heterojunction structure including a buffer layer over the semiconductor substrate and a barrier layer over the buffer layer;
a first III-N transistor formed in a first portion of the active area, the first III-N transistor including a first source region, a first drain region, and a first gate region, wherein the first source region, the first drain region, and the first gate region extend parallel to one another;
a second III-N transistor formed in a second portion of the active area, the second III-N transistor including a second source region, a second drain region, and a second gate region, wherein the second source region, the second drain region, and the second gate region extend parallel to one another; and
a III-N gate layer disposed over the barrier layer, the III-N gate layer including:
a first gate portion disposed in the first gate region;
a first gate extension extended from the first gate portion to the isolation region, the first gate extension being proximate to a terminal portion of the first source region;
a second gate portion disposed in the second gate region; and
a second gate extension extended from the second gate portion to the isolation region, the second gate extension being proximate to a terminal portion of the second source region.

11. The semiconductor device of claim 10, further comprising:
a first gate electrode coupled to the first gate portion;
a first gate electrode extension extended from the first gate electrode and coupled to the first gate extension;
a second gate electrode coupled to the second gate portion; and
a second gate electrode extension extended from the second gate electrode and coupled to the second gate extension.

12. The semiconductor device of claim 10, wherein:
the first gate region is disposed on a first side of the first drain region, the first III-N transistor further comprising a third gate region disposed in a second side of the first drain region opposite the first side;
the second gate region is disposed on a first side of the second drain region, the second III-N transistor further comprising a fourth gate region disposed in a second side of the second drain region opposite the first side; and
the III-N gate layer further comprises:
a third gate portion disposed in the third gate region;
a fourth gate portion disposed in the fourth gate region; and
a bridge portion connecting the third gate portion to the fourth gate portion.

13. The semiconductor device of claim 12, further comprising:
a common source region disposed between the third and fourth gate regions, wherein the bridge portion, the third gate portion, and the fourth gate portion at least partially surround the common source region.

14. The semiconductor device of claim 12, further comprising:
a third gate electrode coupled to the third gate portion;
a fourth gate electrode coupled to the fourth gate portion; and
a fifth gate electrode coupled to the bridge portion, wherein the fifth gate electrode connects the third gate electrode to the fourth gate electrode.

15. The semiconductor device of claim 10, wherein the III-N gate layer further includes:
a third gate portion extended from the first gate portion, the first and third gate portions at least partially surrounding a terminal portion of the first drain region; and
a fourth gate portion extended from the second gate portion, the second and fourth gate portions at least partially surrounding a terminal portion of the second drain region.

16. The semiconductor device of claim 15, wherein:
a section of the third gate portion is disposed over the isolation region and implanted with isolation implant species comprising at least one of argon, silicon, fluorine, and nitrogen.

17. The semiconductor device of claim 15, wherein the third gate portion is disposed over the active area.

18. The semiconductor device of claim 10, wherein the first gate extension and the second gate extension each further extends over at least a respective portion of the isolation region.

19. The semiconductor device of claim 18, wherein portions of the first and second gate extensions are implanted with isolation implant species comprising at least one of argon, silicon, fluorine, and nitrogen.

20. A method, comprising:
forming a III-N heterojunction structure over a semiconductor substrate including an active area and an isolation region surrounding the active area, wherein:
the active area includes a source region, a gate region, and a drain region, the source, gate, and drain regions extending parallel to one another; and
the III-N heterojunction structure includes a buffer layer over the semiconductor substrate and a barrier layer over the buffer layer; and
forming a III-N gate layer over the barrier layer, the III-N gate layer including:
a gate portion disposed in the gate region; and
a gate extension extended from the gate portion to the isolation region.

21. The method of claim 20, wherein the gate extension is disposed proximate to a terminal portion of the source region.

22. The method of claim 20, wherein the gate extension further extends over at least a portion of the isolation region.

23. The method of claim 20, further comprising:
forming a gate electrode coupled to the gate portion.

24. The method of claim 23, wherein forming the gate electrode further comprises:
forming a gate electrode extension extended from the gate electrode and coupled to the gate extension.

25. The method of claim 20, further comprising:
implanting isolation implant species in the isolation region after forming the III-N gate layer, the isolation implant species including at least one of argon, silicon, fluorine, and nitrogen.

26. The method of claim 25, wherein:
the gate portion is a first gate portion, the III-N gate layer further including a second gate portion extended from the gate portion, the first and second gate portions at least partially surrounding a terminal portion of the drain region, wherein implanting the isolation implant species in the isolation region includes implanting the isolation implant species in a section of the second gate portion located in the isolation region.

27. The method of claim 25, wherein:
the gate portion is a first gate portion, the III-N gate layer further including a second gate portion extended from the gate portion, the first and second gate portions at least partially surrounding a terminal portion of the drain region, wherein the first and second gate portions are masked while implanting the isolation implant species in the isolation region.
